(19) United States
(12) Patent Application Publication
(10) Pub. No.: US 2010/0139733 A1
(43) Pub. Date: Jun. 10, 2010

(54) FUSED WIRING HARNESS FOR A PHOTOVOLTAIC SYSTEM

(75) Inventors: Ralf Jonczyk, Newark, DE (US); Veasna Sok, Newark, DE (US)

Correspondence Address: McNees Wallace & Nurick, LLC, 100 Pine Street, P.O. Box 1166, Harrisburg, PA, 17108-1166, US

(73) Assignee: GENERAL ELECTRIC COMPANY, Schenectady, NY (US)

(21) Appl. No.: 12/542,760

(22) Filed: Aug. 18, 2009

(51) Int. Cl. H01L 31/05; H02B 1/20; H01R 43/00

(52) U.S. Cl. 136/244; 361/826; 29/825; 174/72 A

(57) ABSTRACT

A fused wiring harness having a fused wiring assembly and a second wiring assembly. The fused wiring assembly includes a first primary conductor, a first secondary fused conductor, and a second secondary fused conductor. The first secondary fused conductor is conductively connected to the first primary conductor at a first junction. The second secondary fused conductor is conductively connected to the first primary conductor at a second junction. The second wiring assembly includes a second primary conductor, a first secondary conductor, and a second secondary conductor. The first secondary conductor is conductively connected to the second primary conductor at a third junction. The fused wiring harness further includes a first overmold portion at least partially enveloping the first junction and the third junction, thereby securing the fused wiring assembly to the second wiring assembly.

### FIELD OF THE INVENTION

The present disclosure is directed to a fused wiring harness for a photovoltaic system.

### BACKGROUND

Large photovoltaic arrays are now being installed in the United States and have been installed in the European Union for some time. Recently, thin-film photovoltaic (PV) modules having a high voltage have been introduced. These PV modules present a challenge to the direct current (DC) collection system that collects the power output from each individual PV module and conducts it to the inverter, where it is inverted from DC to alternating current (AC) and subsequently fed to the power grid. More specifically, there is a voltage limit of 600V placed on the system by the National Electric Code (NEC) and to a lesser degree by inverter limitations. For many thin-film PV modules having a high voltage, as few as two of these modules can be connected in series, thus requiring the installation of several thousand individual circuits during the deployment of large photovoltaic arrays. Additionally, in many instances, there is a requirement that each of these individual circuits be protected by a fuse.

Accordingly, there is a need for a wiring harness for a PV system that protects each individual circuit and that provides for ease of installation during, for example, the deployment of large photovoltaic arrays.

### SUMMARY

One aspect of the disclosure includes a fused wiring harness for a photovoltaic system. The fused wiring harness includes a fused wiring assembly and a second wiring assembly. The fused wiring assembly includes a first primary conductor, a first secondary fused conductor, and a second secondary fused conductor. The first secondary fused conductor, which is conductively connected to the first primary conductor at a first junction, includes a first connector that is configured to conductively connect to a first circuit comprising a photovoltaic module. The second secondary fused conductor, which is conductively connected to the first primary conductor at a second junction, includes a second connector, that is configured to conductively connect to a second circuit comprising a photovoltaic module. The second wiring assembly includes a second primary conductor, a first secondary conductor, and a second secondary conductor. The first secondary conductor, which is conductively connected to the second primary conductor at a third junction, includes a third connector that is configured to conductively connect to the first circuit comprising a photovoltaic module. The second secondary conductor, which is conductively connected to the second primary conductor at a fourth junction, includes a fourth connector that is configured to conductively connect to the second circuit comprising a photovoltaic module. The fused wiring harness further includes a first overmold portion at least partially enveloping the first junction and the third junction, thereby securing the fused wiring assembly to the second wiring assembly.

Another aspect of the present disclosure includes a photovoltaic system. The photovoltaic system includes a plurality of photovoltaic modules having at least a first photovoltaic module and a second photovoltaic module. The photovoltaic system further includes a fused wiring harness having a fused wiring assembly and a second wiring assembly. The fused wiring assembly includes a first primary conductor, a first secondary fused conductor, and a second secondary fused conductor. The first secondary fused conductor, which is conductively connected to the first primary conductor at a first junction, includes a first connector that is conductively connected to the first photovoltaic module. The second secondary fused conductor, which is conductively connected to the first primary conductor at a second junction, includes a second connector that is conductively connected to the second photovoltaic module. The second wiring assembly includes a second primary conductor, a first secondary conductor, and a second secondary conductor. The first secondary conductor, which is conductively connected to the second primary conductor at a third junction, includes a third connector that is conductively connected to the first photovoltaic module. The second secondary conductor, which is conductively connected to the second primary conductor at a fourth junction, includes a fourth connector that is conductively connected to the second photovoltaic module. The fused wiring harness further includes a first overmold portion at least partially enveloping the first junction and the third junction, thereby securing the fused wiring assembly to the second wiring assembly.

Still another aspect of the present disclosure includes a method for installing a photovoltaic system. The method includes providing a first circuit that includes a first photovoltaic module and providing a second circuit that includes a second photovoltaic module. The method further includes providing a fused wiring assembly. The fused wiring assembly includes a first primary conductor, a first secondary fused conductor, and a second secondary fused conductor. The first secondary fused conductor, which is conductively connected to the first primary conductor at a first junction, includes a first connector that is conductively connected to the first photovoltaic module. The second secondary fused conductor, which is conductively connected to the first primary conductor at a second junction, includes a second connector that is conductively connected to the second photovoltaic module. The second wiring assembly includes a second primary conductor, a first secondary conductor, and a second secondary conductor. The first secondary conductor, which is conductively connected to the second primary conductor at a third junction, includes a third connector that is conductively connected to the first photovoltaic module. The second secondary conductor, which is conductively connected to the second primary conductor at a fourth junction, includes a fourth connector that is conductively connected to the second photovoltaic module. The fused wiring harness further includes a first overmold portion at least partially enveloping the first junction and the third junction, thereby securing the fused wiring assembly to the second wiring assembly. The method includes connecting the first connector to the first circuit, connecting the second connector to the second circuit, connecting the third connector to the first circuit, and connecting the fourth connector to the second circuit.

An advantage of the present disclosure includes the ability to protect each individual circuit and the ability to provide for the relative ease of installation of large photovoltaic arrays by significantly reducing the wire length required, thereby conserving copper, and by reducing the number of field splices required.

Another advantage of the present disclosure includes the ability to combine current from several PV modules to more closely match the current carrying capacity of the wiring (12 AWG minimum per the NEC) used in conducting current generated by the PV modules.

Other features and advantages of the present disclosure will be apparent from the following more detailed description of the preferred embodiment, taken in conjunction with the accompanying drawings which illustrate, by way of example, the principles of the disclosure.

### BRIEF DESCRIPTION OF THE DRAWINGS

FIG. 1 is a partial top view of an exemplary component of an embodiment of the fused wiring harness.

FIG. 2 is a partial top view of another exemplary component of the same embodiment of the fused wiring harness.

FIG. 3 is a partial top view of the embodiment of the fused wiring harness comprising the components shown respectively in FIGS. 1 and 2.

FIG. 4 is an enlarged cross-section view, taken along lines 4-4 of FIG. 3, of an exemplary first junction of the embodiment of the fused wiring harness.

FIG. 5 is an enlarged view of an exemplary secondary fused wiring assembly of the same embodiment of the fused wiring harness shown in FIG. 3.

FIG. 6 is an enlarged cross-section view, taken along lines 6-6 of FIG. 5, of the exemplary secondary fused wiring assembly.

FIG. 7 is a partial top view of an alternate embodiment of the fused wiring harness.

FIG. 8 is a partial top view of another alternate embodiment of the fused wiring harness.

FIG. 9 is a partial top view of another embodiment of the fused wiring harness comprising the exemplary components shown respectively in FIGS. 1 and 2.

FIG. 10 is a partial top view of another embodiment of the fused wiring harness comprising the exemplary components shown respectively in FIGS. 1 and 2.

FIG. 11, which is alternatively supplemented by FIGS. 7 or 8, is a partial top view of another embodiment of the fused wiring harness.

FIG. 12 is a schematic representation of a photovoltaic system comprising embodiments of the fused wiring harness.

Wherever possible, the same reference numbers will be used throughout the drawings to refer to the same or like parts.

### DETAILED DESCRIPTION OF THE INVENTION

The following detailed description includes references to the accompanying drawings, which form a part of the detailed description. The drawings show, by way of illustration, specific embodiments in which the disclosure may be practiced. These embodiments, which are also referred to herein as “examples,” are described in enough detail to enable those skilled in the art to practice the disclosure. The embodiments may be combined, other embodiments may be utilized, or structural, logical and electrical changes may be made without departing from the scope of the present disclosure. The following detailed description is, therefore, not to be taken in a limiting sense, and the scope of the present disclosure is defined by the appended claims and their equivalents.

In this document, the terms “a” or “an” are used, as is common in patent documents, to include one or more than one. In this document, the term “or” is used to refer to a nonexclusive or, unless otherwise indicated.

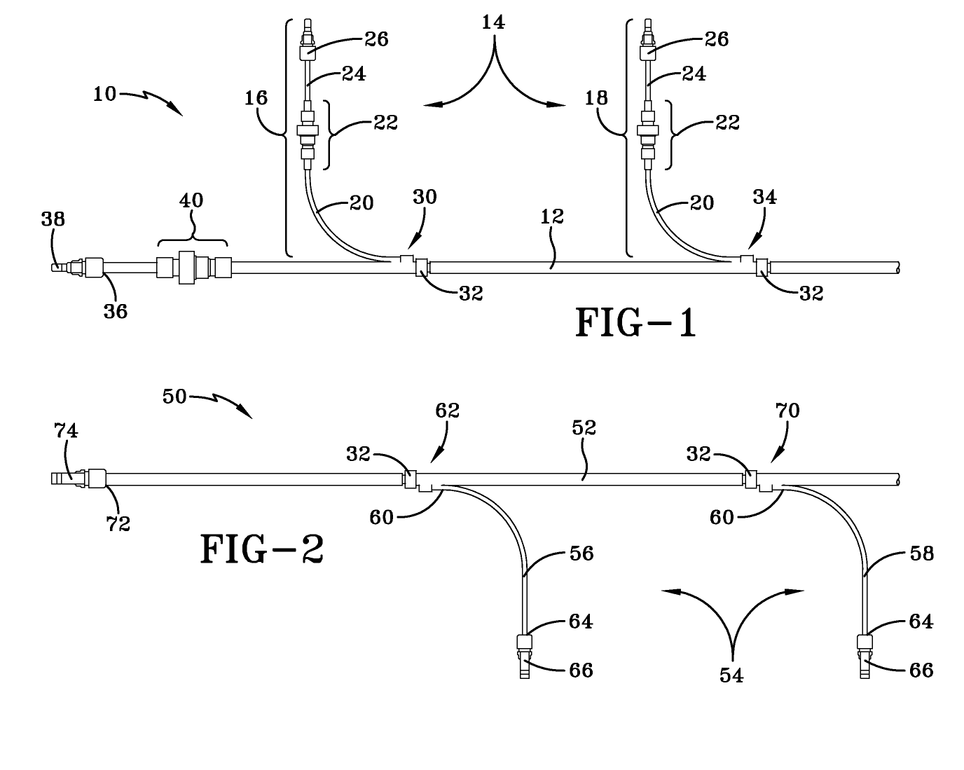

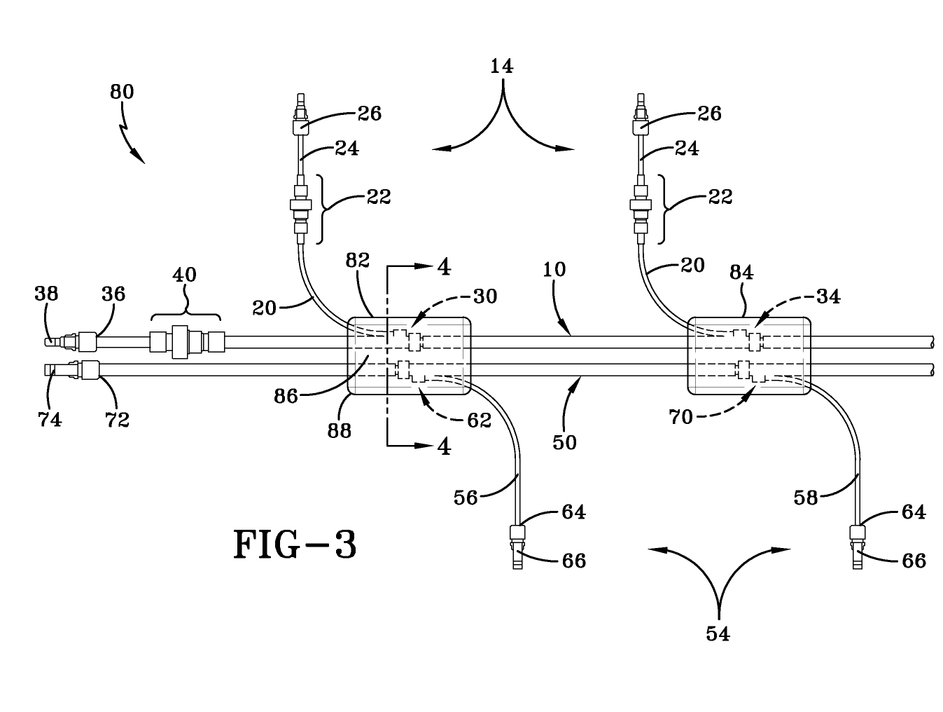

FIGS. 1 and 2 respectively show two components of the fused wiring harness (see FIG. 3 at 80): a fused wiring assembly 10 and an unfused wiring assembly 50. Referring to FIG. 1, fused wiring assembly 10 includes a first primary conductor 12 and a plurality of secondary fused conductors 14. More specifically, the plurality of secondary fused conductors 14 includes without limitation a first secondary fused conductor 16 and a second secondary fused conductor 18. First secondary fused conductor 16 includes, in series, a first segment 20, a secondary fuse assembly 22, a second segment 24, and a secondary connector 26. Secondary fuse assembly 22 connects first segment 20 and second segment 24, and second segment 24 connects secondary fuse assembly 22 to secondary connector 26. Stated another way, first secondary fused conductor 16 includes an in-line fuse, meaning that conductor 16 includes a fuse in series between two portions of the same conductor. More generally, as used herein, the adjective “fused” means that the referenced conductor or wiring assembly includes an in-line fuse. The adjective “unfused” means that the referenced conductor or wiring assembly does not include an in-line fuse. First segment 20 conductively connects to first primary conductor 12 at a first junction 30, which in the example shown in FIG. 1, is effected by a crimp barrel 32 or other suitable cable joint. Alternatively, other techniques or components may be used to conductively connect first segment 20 of first secondary fused conductor 16 to first primary conductor 12. Exemplary techniques or components include soldering, screw terminals, welding, and splicing. While not so limited, an exemplary primary conductor is 8 AWG (American Wire Gauge) USE-2 (Underground Service-Entrance Type 2) PV wire that has a voltage rating of at least 600 V. Wiring of this type may be insulated by either PVC (polyvinyl chloride) or XLPE (cross-linked polyethylene) and is heat resistant, moisture resistant, and sunlight resistant. While not so limited, an exemplary secondary conductor is 10 AWG or 12 AWG USE-2 PV wire that has a voltage rating of at least 600 V. Wiring of this type may be insulated by either PVC (polyvinyl chloride) or XLPE (cross-linked polyethylene) and is heat resistant, moisture resistant, and sunlight resistant. Secondary connector 26 is configured to connect to a PV module and, preferably, is a male connector, as shown in FIG. 1. An exemplary secondary connector 26 is a male latching connector that is compatible with 10 AWG or 12 AWG USE-2 or PV wire and has a current rating of 30 amps and a voltage rating of 1000V (600V UL). Exemplary contact materials for the male latching connector may include tin-plated copper.

Second secondary fused conductor 18 is substantially equivalent to first secondary fused conductor 16. For example, second secondary fused conductor 18 includes, in series, a first segment 20, a secondary fuse assembly 22, a second segment 24, and a connector 26. First segment 20 of second secondary fused conductor 18 conductively connects to first primary conductor 12 at a second junction 34, which, as shown in FIG. 1, can be effected by a crimp barrel 32 or other suitable cable joint.

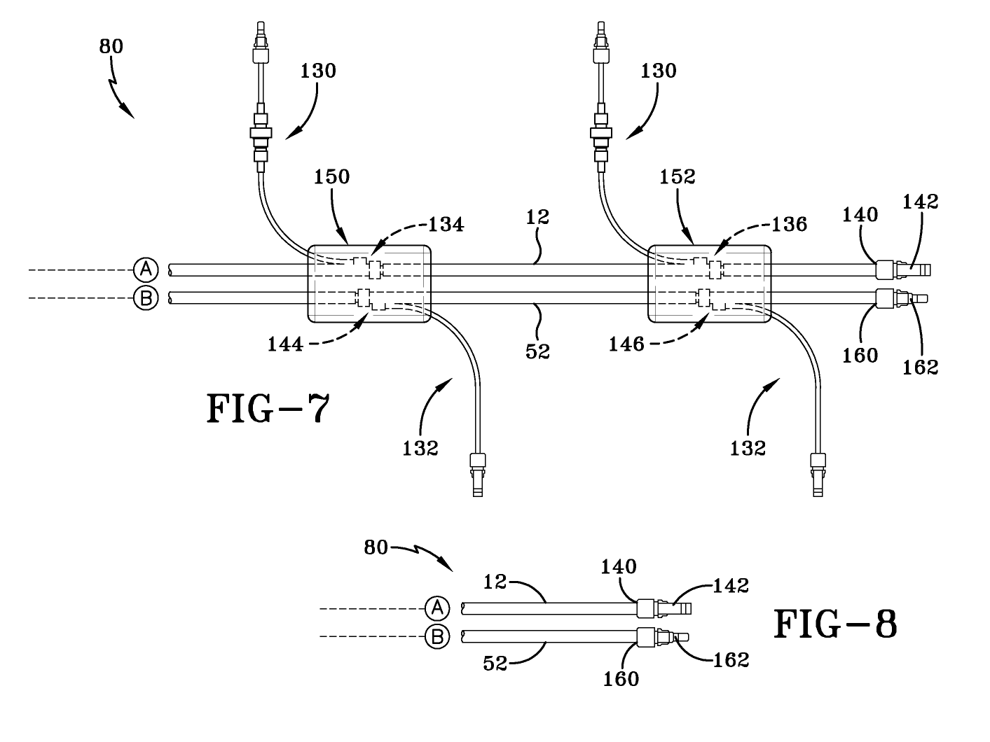

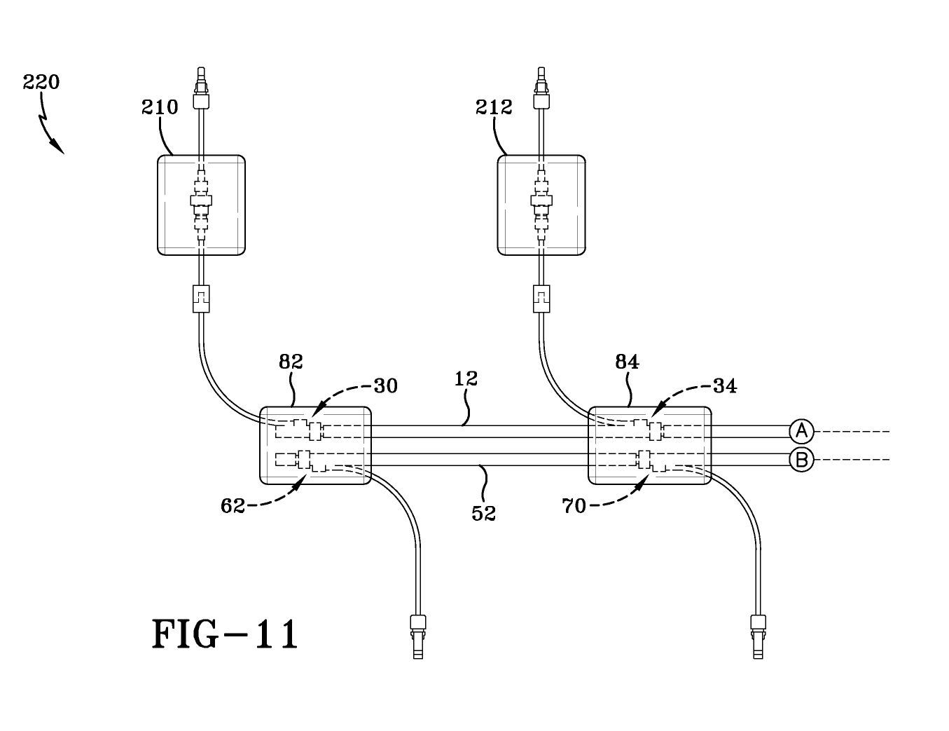

First primary conductor 12 includes a first end 36 having a first primary connector 38 and a second end (see, e.g., FIG. 7 at 140), which is discussed later. An exemplary first primary connector 38 is a male latching connector that is compatible with 8 AWG USE-2 or PV wire and has a current rating of 30 amps and a voltage rating of 1000V (600V UL). First primary conductor 38 includes a primary fuse assembly 40 proximate to first end 36. More particularly, primary fuse assembly 40 is in series between first end 36 and first junction 30. In turn, first junction 30 is in series between primary fuse assembly 40 and second junction 34. An exemplary primary fuse for use in the primary fuse assembly 40 is a fast-acting 5A 600 VDC midget fuse. First primary connector 38 is configured to connect first end 36 of first primary conductor 12 to a primary conductor of another fused wiring assembly. Exemplary contact materials for the first primary connector 38 may include tin-plated copper. In another embodiment, first primary conductor 12 terminates at first junction 30 (see, e.g., FIG. 11).

Referring to FIG. 2, unfused wiring assembly 50 includes a second primary conductor 52 and a plurality of secondary unfused conductors 54. Plurality of secondary unfused conductors 54 includes without limitation a first secondary unfused conductor 56 and a second secondary unfused conductor 58. Second end 64 of first secondary unfused conductor 56 includes a connector 66, which may include a female latching connector. First secondary unfused conductor 56 includes a first end 60 and a second end 62. First end 60 conductively connects to second primary conductor 52 at a third junction 62, which in the example shown in FIG. 2, is effected by a crimp barrel 32 or other cable joint. Alternatively, similar to fused wiring assembly 10, other techniques or components may be used to conductively connect first end 60 of first secondary unfused conductor 56 to second primary conductor 52. Exemplary techniques or components include soldering, screw terminals, welding, and splicing. Similar to fused wiring assembly 10, an exemplary primary conductor may be 8 AWG USE-2 PV wire having a voltage rating of at least 600 V. An exemplary secondary conductor may be 10 AWG or 12 AWG USE-2 PV wire having a voltage rating of at least 600 V. As in fused wiring assembly 10, wiring is heat resistant, moisture resistant, and sunlight resistant, and may be insulated by either PVC (polyvinyl chloride) or XLPE (cross-linked polyethylene). Connector 66 is configured to connect to a PV module and, preferably, is a female connector, as shown in FIG. 2. An exemplary connector 66 is a female latching connector that is compatible with 10 AWG or 12 AWG USE-2 or PV wire and has a current rating of 30 amps and a voltage rating of 1000V (600V UL). Exemplary contact materials for connector 66 may include tin-plated copper.

Second secondary unfused conductor 58 is substantially equivalent to first secondary unfused conductor 56. For example, second secondary unfused conductor 58 includes a first end 60 and a second end 64. First end 60 conductively connects to second primary conductor 52 at a fourth junction 70, which in the example shown in FIG. 2, is effected by a crimp barrel 32 or other cable joint. Second end 64 includes a connector 66, preferably a female latching connector.

Second primary conductor 52 includes a first end 72 having a second primary connector 74 and a second end (see, e.g., FIG. 7 at 160), which is discussed later. An exemplary second primary connector 74 is a female latching connector that is compatible with 8 AWG USE-2 or PV wire and has a current rating of 30 amps and a voltage rating of 1000V (600V UL). Third junction 62 is in series between first end 72 and fourth junction 70. Unlike first primary conductor 12, secondary primary conductor 52 does not include a fuse proximate to first end 72. Second primary connector 74 is configured to connect first end 72 of second primary conductor 52 to a second primary conductor of another unfused wiring assembly. In another embodiment, second primary conductor 52 terminates at third junction 62 (see, e.g., FIG. 11).

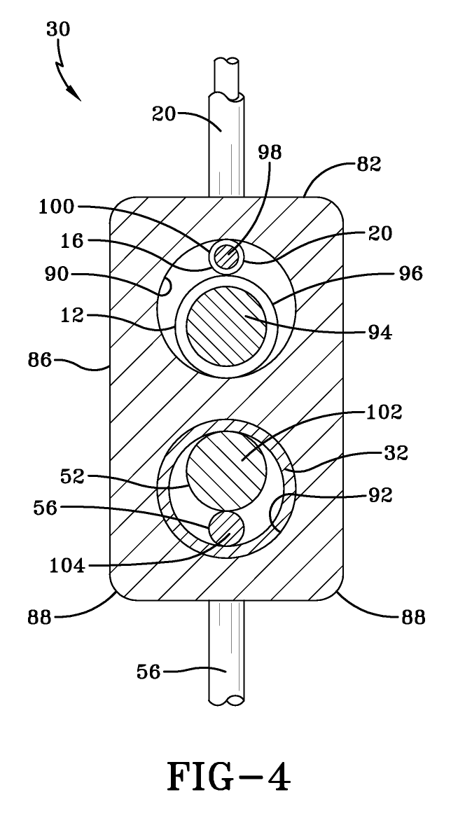

Referring to FIG. 3, in which a fused wiring harness 80 is shown, fused wiring assembly 10 and unfused wiring assembly 50 are secured to one another by a first overmold portion 82 and a second overmold portion 84. First overmold portion 82 at least partially envelops first junction 30 of fused wiring assembly 10 and third junction 62 of unfused wiring assembly 50. Second overmold portion 84 at least partially envelops second junction 34 of fused wiring assembly 10 and fourth junction 70 of unfused wiring assembly 50. The overmold portions 82, 84 can be formed from a high-performance thermoplastic material such as a thermoplastic elastomer (TPE). Exemplary thermoplastic elastomers include, without limitation, thermoplastic vulcanizates (TPV). Suitable materials for overmolding are heat resistant, moisture resistant, and sunlight resistant. Preferably, first overmold portion 82 protects first junction 30 and third junction 62 from damage due to heat, moisture, and sunlight, especially in applications where fused wiring harness 80 is exposed to the weather. Second overmold portion 84 similarly protects second junction 34 and fourth junction 70 from such damage. Both first overmold portion 82 and second overmold portion 84 are approximately cuboid in geometry, although other geometries may be substituted. Preferably, as indicated in FIGS. 3 and 4, the exterior surface 86 of first overmold portion 82 does not have a sharp corner or edge. Instead, exterior surface 86 has rounded edges 88 to reduce the risk of damage to the wiring in their proximity. Second overmold portion 84 is similar to first overmold portion 82 in this regard.

Referring to FIG. 4, which is a cross-section view, first overmold portion 82 includes a first through-opening 90 and a second through-opening 92. First primary conductor 12 and first segment 20 of first secondary fused conductor 16 are present within first through-opening 90. The conductive core 94 and the insulative exterior 96 of first primary conductor 12 are visible in FIG. 4, as are the conductive core 98 and the insulative exterior 100 of first secondary fused conductor 16. Second primary conductor 52 and first secondary unfused conductor 56 are present within second through-opening 92. Because line 4-4 of FIG. 3 intersects crimp barrel 32 of third junction 62, crimp barrel 32 is visible in FIG. 4. The conductive core 102 of second primary conductor 52 contacts the conductive core 104 of first secondary unfused conductor 56, as the portions of these wires aligned with crimp barrel 32 are not insulated to yield a conductive connection. As stated previously, rounded edges 88 of exterior surface 86 of first overmold portion 82 are shown in FIG. 4.

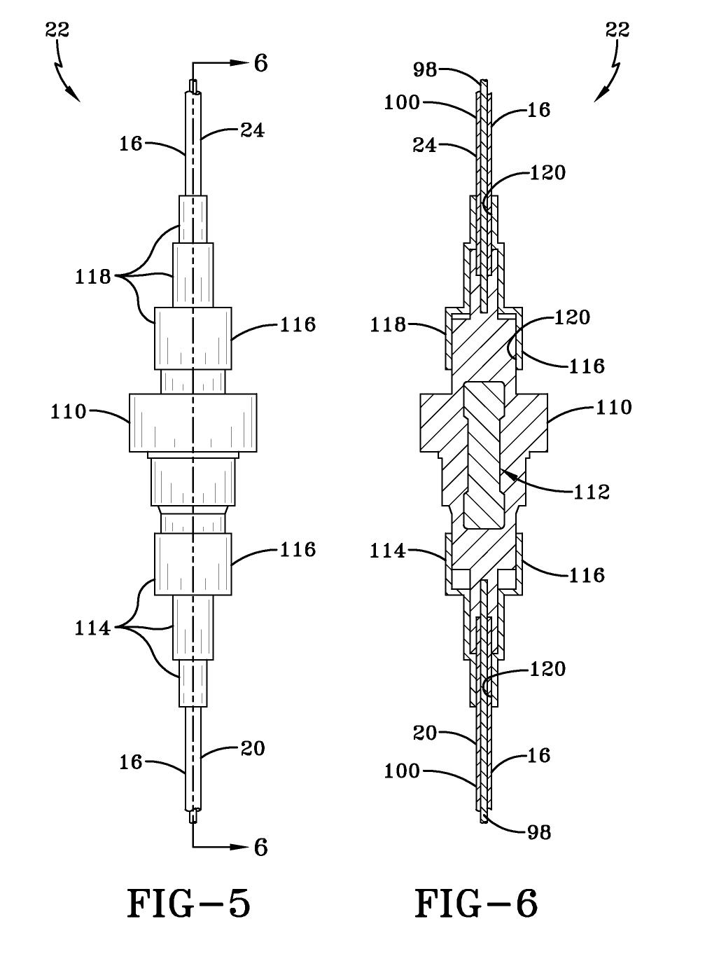

FIGS. 5 and 6 collectively show various components and features of secondary fuse assembly 22. FIG. 5, which is an enlarged view of secondary fuse assembly 22, shows a fuse holder 110. As shown in FIG. 6, which is an enlarged section view, fuse holder 110 encloses a fuse 112, thereby protecting fuse 112 from the environment and preventing contact by persons or objects, including other conductors, all of which could prematurely short fuse 112. A first section 114 of shrink wrap 116 aids in securing first segment 20 of first secondary fused conductor 16 to fuse holder 110. Similarly, a second section 118 of shrink wrap 116 aids in securing second segment 24 of first secondary fused conductor 16 to fuse holder 110. Preferably, shrink wrap 116 includes an adhesive lining on an inner surface 120 (see FIG. 6) to encourage a reliable and enduring connection. First secondary fused conductor 16 includes a conductive core 98 and an insulative exterior 100, both of which are shown in FIG. 6, in relation to both first segment 20 and second segment 24. Primary fuse assembly 40 (see FIG. 1) is substantially equivalent to secondary fuse assembly 22. Primary fuse assembly 40 and secondary fuse assembly 22 may be waterproof and sunlight resistant.

FIGS. 7 and 8, which relate to fused wiring harness 80 (see FIG. 3), each show an option relating to a point (A) of first primary conductor 12 and a point (B) of second primary conductor 52. As shown in FIG. 7, embodiment 80 can include additional secondary fused conductors 130 and additional secondary unfused conductors 132. Additional secondary fused conductors 130 are respectively conductively connected to first primary conductor 12 at a fifth junction 134 and a sixth junction 136. Second end 140 includes a connector 142, preferably a female latching connector as shown in FIG. 7. Additional secondary unfused conductors 132 are respectively conductively connected to second primary conductor 52 at a seventh junction 144 and an eighth junction 146. A third overmold portion 150 encloses fifth junction 134 and seventh junction 144, and a fourth overmold portion 152 encloses sixth junction 136 and eighth junction 146. Second end 160 of second primary connector 52 includes a connector 162, preferably a male latching connector as shown in FIG. 7.

Referring to FIG. 8, which shows another option relating to a point (A) of first primary conductor 12 and a point (B) of second primary conductor 52 (see FIG. 3), second end 140 of first primary conductor 12 and second end 160 of second primary conductor 52 terminate respectively in a female connector 142 and a male connector 162. No additional secondary fused or unfused conductor is included.

FIGS. 7 and 8 in combination are intended to underscore an advantage of the fused wiring harness, specifically, that there is flexibility in the number of junctions, which is determined by the number of fused secondary conductors and corresponding unfused secondary conductors. In turn, this number can be influenced by the number of individual PV modules that can be connected in series in a single circuit without exceeding the final voltage, which is presently 600V in the United States. If a relatively large number of individual PV modules can be connected in a single circuit, then fewer junctions may be needed in the fused wiring harness. Contrarily, if only a relatively small number of individual PV modules can be connected in a single circuit without exceeding the final voltage (e.g., 600 V), then additional junctions in the fused wiring harness may be desirable. In these situations, a large plurality of fused wiring harnesses may be used to establish the necessary electrical connections. The final voltage even may be higher in some jurisdictions (e.g., 1000V), or a higher final voltage may be permissible provided there is compliance with more stringent sections of the NEC.

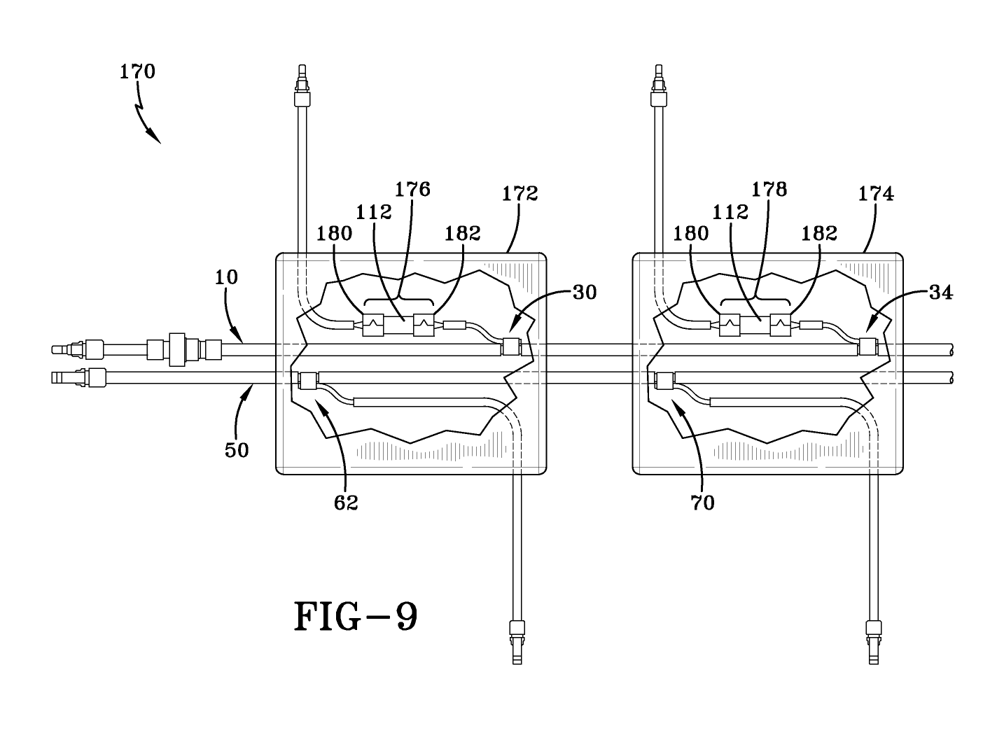

FIG. 9 shows another fused wiring harness 170. As shown in FIG. 9, fused wiring assembly 10 and unfused wiring assembly 50 are secured to one another by a first overmold portion 172 and a second overmold portion 174. First overmold portion 172 at least partially envelops a first fuse assembly 176, in addition to first junction 30 of fused wiring assembly 10 and third junction 62 of unfused wiring assembly 50. Similarly, second overmold portion 174 at least partially envelops a second fuse assembly 178, in addition to second junction 34 of fused wiring assembly 10 and fourth junction 70 of unfused wiring assembly 50. An advantage of fused wiring harness 170 is that fuse assemblies 176, 178 are afforded significant protection from heat, moisture, and/or sunlight. As shown in FIG. 9, the protection afforded by the overmold portions is sufficient to render a fuse holder (see, e.g., FIG. 6 at 110) and shrink wrap (see, e.g., FIG. 6 at 116) unnecessary, potentially generating cost savings and increasing the ease of manufacture. Respective fuses 112 are secured by a first metal contact 180 and a second metal contact 182, in combination.

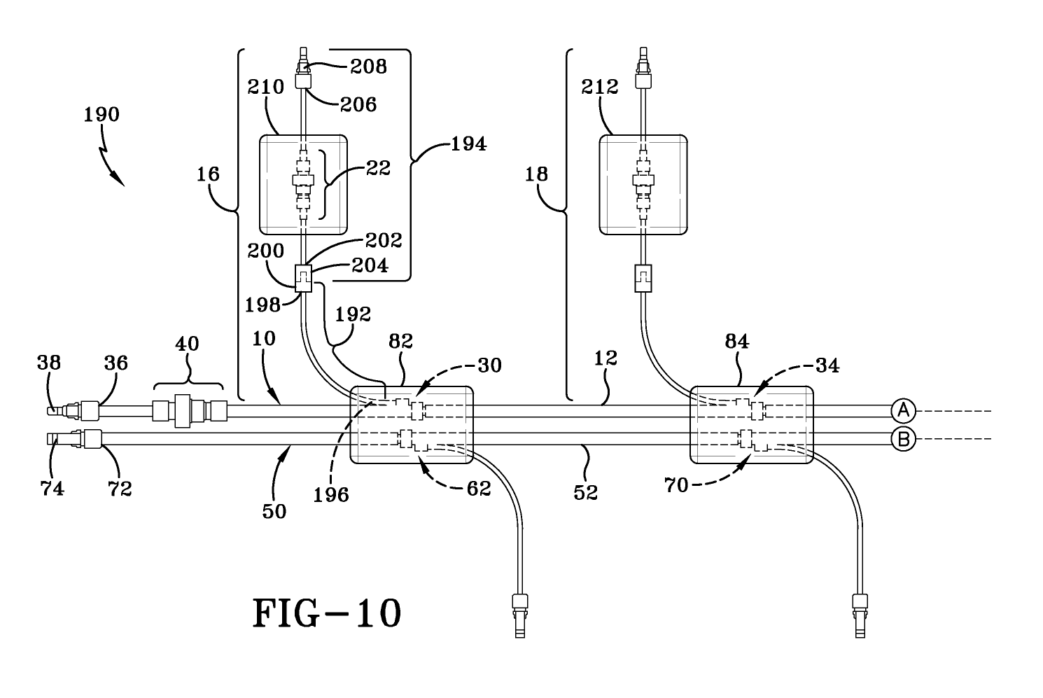

FIG. 10 shows another fused wiring harness 190. As in fused wiring harness 80 (see FIG. 3), fused wiring assembly 10 and unfused wiring assembly 50 of fused wiring harness 190 are secured to one another by a first overmold portion 82 and a second overmold portion 84. First overmold portion 82 at least partially envelops first junction 30 of fused wiring assembly 10 and third junction 62 of unfused wiring assembly 50. Second overmold portion 84 at least partially envelops second junction 34 of fused wiring assembly 10 and fourth junction 70 of unfused wiring assembly 10. Among the differences between fused wiring harness 190 and fused wiring harness 80 (see FIG. 3) is that first secondary fused conductor 16 includes an unfused portion 192 and a detachable fused portion 194. Unfused portion 192 includes a first end 196 that conductively connects to first primary conductor 12 and includes a second end 198 that terminates in a connector 200, which may be a male connector, as shown in FIG. 10. Detachable fused portion 194 includes a third end 202 having a corresponding connector 204, which may be a female connector, configured to releasably connect to connector 200 of unfused portion 192. Detachable fused portion 194 includes a fourth end 206 having a connector 208, which may be a male connector, configured to connect to a PV module. Detachable fused portion 194 includes a fuse assembly 22 disposed in series between third end 202 and fourth end 206. Fuse assembly 22 includes a fuse 112 enclosed in a fuse holder 110, as previously discussed (see FIG. 6). A first discrete fuse overmold portion 210 encloses and protects fuse assembly 22 and, preferably, does not significantly encroach third end 202 or fourth end 206 such as to inhibit a user from (1) detaching detachable fused portion 194 from unfused portion 192 by disengaging connectors 200, 204 and (2) detaching detachable fused portion 194 from a PV module by disengaging connector 208 from the PV module. The foregoing features of embodiment 190 allow a user to readily replace fuse 112 (see FIG. 6) by detaching detachable fused portion 194 and attaching a replacement detachable fused portion. In some instances, the protection afforded by first discrete fuse overmold portion 210 may be sufficient to render fuse holder 110 unnecessary, potentially generating cost savings and increasing the ease of manufacture. As shown in FIG. 10, second secondary fused conductor 18 is substantially equivalent to first secondary fused conductor and includes a second discrete fuse overmold portion 212.

FIG. 11 shows another fused wiring harness 220, which is similar to fused wiring harness 190 shown and described above in the description of FIG. 10. A significant difference between fused wiring harness 220 and fused wiring harness 190 is that, in fused wiring harness 220, first primary conductor 12 terminates at first junction 30 and second primary conductor 52 terminates at third junction 62. As in fused wiring harness 80 (see FIG. 3) both first junction 30 and third junction 62 are enclosed in first overmold portion 82.

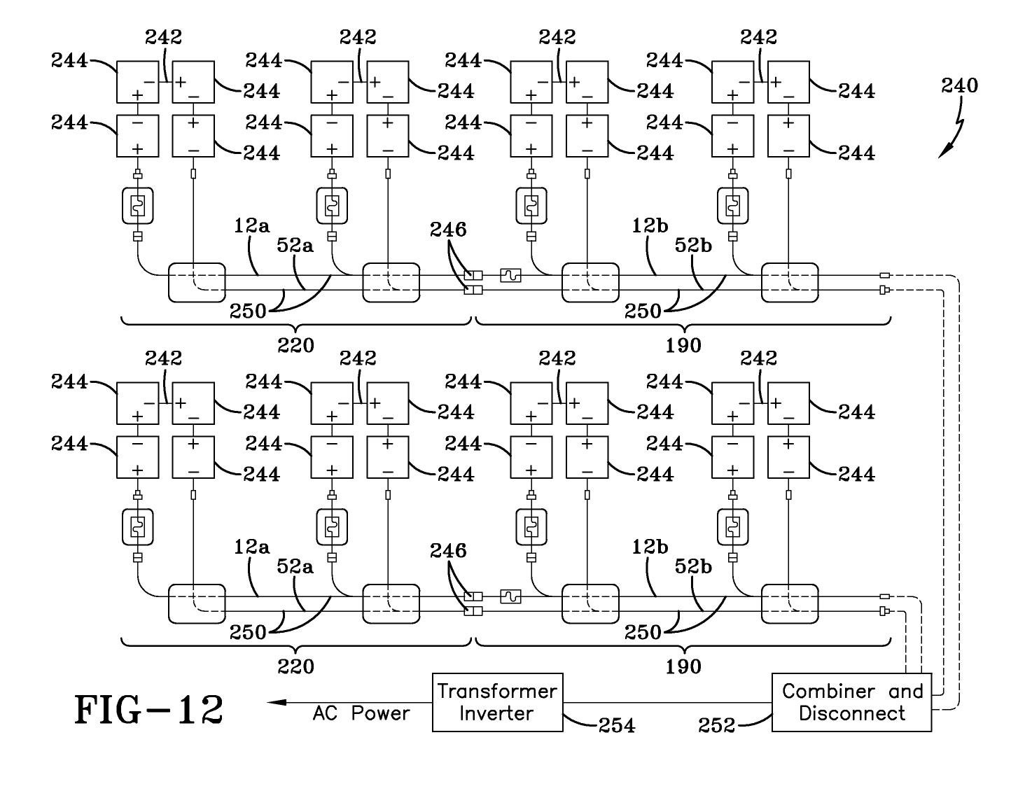

FIG. 12 is a simplified schematic representation showing fused wiring harness 190 (see FIG. 10) and fused wiring harness 220 (see FIG. 11) deployed in an exemplary PV system 240. Fused wiring harness 220 is shown connected to two circuits 242, each of which includes a series of four PV modules 244. Similarly, fused wiring harness 190 is shown connected to two other circuits 242, each of which also includes a series of four PV modules 244. Fused wiring harness 220 is connected to fused wiring harness 190 at connection points 246, allowing first primary conductors 12a, 12b and second primary conductors 52a, 52b to function as a bus line 250. The electrical current resulting from capture of solar energy by the PV modules is conducted along bus line 250 to a combiner and disconnect 252. Combiner 252 also receives electrical current from another bank of four PV modules, which are similarly connected to combiner by a duplicate fused wiring harness 220 and a duplicate fused wiring harness 190. Current is conducted to a transformer inverter 254, where it is converted from direct current (DC) to alternating (AC) power.

The embodiments of the fused wiring harness disclosed herein have been described as having certain connector types (e.g., male interlocking connector, female interlocking connector) at certain positions. The types of connectors and their positions, as identified in reference to these embodiments, are not intended to be limiting. For example, male connectors may be substituted for female connectors, while female connectors are substituted for male connectors. Additionally, other suitable electrical connectors, as will be identifiable by a person of ordinary skill in the relevant art, may be substituted in whole or in part.

While the invention has been described with reference to a preferred embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A fused wiring harness for a photovoltaic system, the fused wiring harness comprising:
a fused wiring assembly comprising:
a first primary conductor;
a first secondary fused conductor being conductively connected to the first primary conductor at a first junction, the first secondary fused conductor comprising a first connector, the first connector being configured to conductively connect to a first circuit comprising a photovoltaic module; and,
a second secondary fused conductor being conductively connected to the first primary conductor at a second junction, the second secondary fused conductor comprising a second connector, the second connector being configured to conductively connect to a second circuit comprising a photovoltaic module; and,
a second wiring assembly comprising:
a second primary conductor;
a first secondary conductor being conductively connected to the second primary conductor at a third junction, the first secondary conductor comprising a third connector, the third connector being configured to conductively connect to the first circuit comprising a photovoltaic module; and,
a second secondary conductor being conductively connected to the second primary conductor at a fourth junction, the second secondary conductor comprising a fourth connector, the fourth connector being configured to conductively connect to the second circuit comprising a photovoltaic module; and,
the fused wiring harness further comprising a first overmold portion at least partially enveloping the first junction and the third junction, thereby securing the fused wiring assembly to the second wiring assembly.

2. The fused wiring harness of claim 1, wherein the first secondary fused conductor comprises a fuse that is enclosed within a fuse holder.

3. The fused wiring harness of claim 1, wherein the first overmold portion at least partially envelops a fuse.

4. The fused wiring harness of claim 2, wherein the first overmold portion at least partially envelops the fuse holder and the fuse.

5. The fused wiring harness of claim 1, further comprising a discrete second overmold portion that at least partially envelops a fuse.

6. The fused wiring harness of claim 2, further comprising a discrete second overmold portion that at least partially envelops the fuse holder and the fuse.

7. The fused wiring harness of claim 1, further comprising a second overmold portion that at least partially envelops the second junction and the fourth junction.

8. The fused wiring harness of claim 1, wherein the first primary conductor comprises a fifth connector, the fifth connector being configured to conductively connect to a device selected from the group consisting of a second fused wiring harness, a combiner, a disconnect, an inverter, and a transformer.

9. The fused wiring harness of claim 8, wherein the first primary conductor further comprises a fuse disposed between a first end and the first junction, and wherein a sixth connector is attached to the first end, the sixth connector being configured to conductively connect to a third fused wiring harness.

10. The fused wiring harness of claim 1, wherein the first secondary conductor is unfused.

11. The fused wiring harness of claim 1, wherein the second wiring assembly is unfused.

12. A photovoltaic system comprising:
a plurality of photovoltaic modules comprising at least a first photovoltaic module and a second photovoltaic module;
a fused wiring harness comprising:
a fused wiring assembly comprising:
a first primary conductor;
a first secondary fused conductor being conductively connected to the first primary conductor at a first junction, the first secondary fused conductor comprising a first connector, the first connector being conductively connected to the first photovoltaic module; and,
a second secondary fused conductor being conductively connected to the first primary conductor at a second junction, the second secondary fused conductor comprising a second connector, the second connector being conductively connected to the second photovoltaic module; and,
a second wiring assembly comprising:
a second primary conductor;
a first secondary conductor being conductively connected to the second primary conductor at a third junction, the first secondary conductor comprising a third connector, the third connector being conductively connected to the first photovoltaic module; and,
a second secondary conductor being conductively connected to the second primary conductor at a fourth junction, the second secondary conductor comprising a fourth connector, the fourth connector being conductively connected to the second photovoltaic module; and,
the fused wiring harness further comprising a first overmold portion at least partially enveloping the first junction and the third junction, thereby securing the fused wiring assembly to the second wiring assembly.

13. The photovoltaic system of claim 12, wherein the first primary conductor further comprises a fifth connector, the fifth connector being configured to conductively connect to a device selected from the group consisting of a second fused wiring harness, a combiner, a disconnect, an inverter, and a transformer.

14. The fused wiring harness of claim 13, wherein the first primary conductor further comprises a fuse disposed between a first end and the first junction, and wherein a sixth connector is attached to the first end, the sixth connector being configured to conductively connect to a third fused wiring harness.

15. The fused wiring harness of claim 12, wherein the second wiring assembly is unfused.

16. A method for installing a photovoltaic system, the method comprising:
providing a first circuit, the first circuit comprising a first photovoltaic module;
providing a second circuit, the second circuit comprising a second photovoltaic module;
providing a fused wiring harness comprising:
a fused wiring assembly comprising:
a first primary conductor;
a first secondary fused conductor being conductively connected to the first primary conductor at a first junction, the first secondary fused conductor comprising a first connector, the first connector being configured to conductively connect to the first circuit; and,
a second secondary fused conductor being conductively connected to the first primary conductor at a second junction, the second secondary fused conductor comprising a second connector, the second connector being configured to conductively connect to the second circuit; and,
a second wiring assembly comprising:
a second primary conductor;
a first secondary conductor being conductively connected to the second primary conductor at a third junction, the first secondary conductor comprising a third connector, the third connector being configured to conductively connect to the first circuit; and,
a second secondary conductor being conductively connected to the second primary conductor at a fourth junction, the second secondary conductor comprising a fourth connector, the fourth connector being configured to conductively connect to the second circuit; and,
the fused wiring harness further comprising a first overmold portion at least partially enveloping the first junction and the third junction, thereby securing the fused wiring assembly to the second wiring assembly;
connecting the first connector to the first circuit;
connecting the second connector to the second circuit;
connecting the third connector to the first circuit; and, connecting the fourth connector to the second circuit.

17. The method of claim 16, wherein the first primary conductor comprises a fifth connector, the fifth connector being configured to conductively connect to a device selected from the group consisting of a second fused wiring harness, a combiner, a disconnect, an inverter, and a transformer.

18. The method of claim 17, further comprising:
providing the device selected from the group consisting of a second fused wiring harness, a combiner, a disconnect, an inverter, and a transformer; and,
connecting the fifth connector to the device.

19. The method of claim 18, wherein the first primary conductor further comprises a fuse disposed between a first end and the first junction, and wherein a sixth connector is attached to the first end, the sixth connector being configured to conductively connect to a third fused wiring harness.

20. The method of claim 19, further comprising:
providing the third fused wiring harness; and,
connecting the sixth connector to the third fused wiring harness.
